(19) United States
(12) Patent Application Publication
(10) Pub. No.: US 2026/0342208 A1
(43) Pub. Date: Oct. 29, 2026

(54) SWITCHED MODE POWER SUPPLY AND METHOD

(71) Applicant: STMicroelectronics International N.V., Geneva (CH)

(72) Inventors: Eric Feltrin, Grenoble (FR); Alexandre Meillereux, Sassenage (FR)

(21) Appl. No.: 19/635,327

(22) Filed: Mar. 31, 2026

(30) Foreign Application Priority Data
Apr. 28, 2025 (FR) FR2504467

(51) Int. Cl. H02M 1/088; H02M 1/00; H02M 3/158; H03K 17/0412

(52) U.S. Cl. CPC H02M 1/088; H02M 1/0009; H02M 3/158; H03K 17/04123; H03K 2217/0063; H03K 2217/0072

(57) ABSTRACT

The present description concerns a switched-mode power supply and method. At each operating cycle, a circuit controls: a first time period in the on state of a high-side switch, constant or proportional to 1/(Vsup-Vout), with Vsup a power supply potential and Vout a regulated voltage supplied by the switched-mode power supply, and, at the end of the first time period, a second time period in the on state of a low-side switch, proportional to the inverse of a first current. A correction circuit compares a second current proportional to Vsup-Vout with a constant current, and supplies the first current equal to a third current plus a fourth current, the fourth current being zero if the second current is greater than the constant current, and proportional to the constant current minus the second current otherwise.

### CROSS-REFERENCE TO RELATED APPLICATIONS

This application claims the priority benefit of French Patent Application No. FR2504467 filed on Apr. 28, 2025, entitled “Switched-mode power supply,” which is hereby incorporated herein by reference to the maximum extent allowable by law.

### TECHNICAL FIELD

The present disclosure generally concerns electronic circuits and methods, and more particularly switched-mode power supplies (SMPSs), preferably of buck type, and methods.

### BACKGROUND

Known switched-mode power supplies comprise a high-side switch and a low-side switch, series-connected between a power supply potential and a reference potential. An intermediate node between the two switches, for example a node connecting the two switches to each other, is coupled to a load to be powered by an inductor (or inductive element). By controlling the on and off states of the high-side and low-side switches, respectively, energy is stored in the inductor, and then, by controlling the off and on states of the high-side and low-side switches, respectively, the energy stored in the inductor is released to the load. Each succession of a phase of energy storage in the inductor and of a phase of energy release to the load forms an operating cycle.

Among these known switched-mode power supplies, switched-mode power supplies operating in pulse-frequency modulation (PFM) and in discontinuous conduction mode (DCM) can be distinguished. In such switched-mode power supplies, two successive operating cycles can be separated from each other by an idle phase during which both switches are in the off state. In such switched-mode power supplies, at each operating cycle, the duration of the phase of energy storage in the inductor is generally determined to end when the current in the inductor reaches a maximum target value. Further, in such switched-mode power supplies, at each operating cycle, the duration of the energy release phase is generally determined to end when the current in the inductor reaches a zero value, after which a new operating cycle can begin.

However, these known switched-mode power supplies have a number of disadvantages.

### SUMMARY

There exists a need to overcome all or part of the disadvantages of switched-mode power supplies of the type described hereabove.

An embodiment overcomes all or part of the disadvantages of switched-mode power supplies of the type described hereabove.

An embodiment provides a switched-mode power supply comprising:
a high-side switch connected between a first node configured to receive a power supply potential and a second node configured to be coupled by an inductor to a node for supplying a regulated voltage;
a low-side switch connected between the second node and a third node configured to receive a reference potential;
a circuit for controlling the high-side and low-side switches configured, at each operating cycle:
to control a first time period in the on state of the high-side switch, the first time period being constant or proportional to 1/(Vsup-Vout), with Vsup the power supply potential and Vout the regulated voltage, and
to control, at the end of the first time period, a second time period in the on state of the low-side switch, the second time period being proportional to the inverse of a first current;
and
a correction circuit configured to:
compare a second current proportional to Vsup-Vout with a constant current;
supply the first current equal to a third current plus a fourth current, the fourth current being zero when the second current is greater than the constant current, and proportional to a subtraction of the second current from the constant current when the second current is lower than the constant current.

According to an embodiment, the control circuit is configured to control the high-side and low-side switches in pulse-frequency modulation and in discontinuous conduction mode.

According to an embodiment, the correction circuit comprises:
a circuit for generating the fourth current configured to supply the fourth current to a current summing node;
a first current source configured to supply the second current to the fourth current generation circuit; and
a second current source configured to supply the constant current to the circuit for generating the fourth current; and
a third current source configured to supply the third current to the current summing node, the first current being available on the current summing node.

According to an embodiment, the circuit for generating the fourth current comprises:
a first MOS transistor having its gate and its drain connected to a current comparison node configured to receive the second current and the constant current so that:
the first transistor is off when the second current is greater than the constant current, and
the first transistor is on when the second current is lower than the constant current, and a current equal to a subtraction of the second current from the constant current flows through the first transistor; and
a second transistor assembled as a current mirror with the first transistor, and configured to supply the fourth current.

According to an embodiment, the first current source comprises:
a MOS transistor and a resistor in series between the first and third nodes;
n operational amplifier having a first input connected to a node connecting the transistor to the resistor, a second input configured to receive the regulated voltage, and an output connected to a gate of the transistor; and
at least one current mirror configured to supply the second current from a current flowing through the transistor.

According to an embodiment, the third current source comprises at least one current mirror configured to supply the third current from the current flowing through the transistor of the first current source.

According to an embodiment, the third current source comprises at least one current mirror with the first current source, the current mirror being configured to supply the third current from the second current flowing through the first current source.

According to an embodiment, the third current is constant or proportional to 1/(Vsup-Vout).

According to an embodiment:
the switched-mode power supply comprises a generator of first voltage ramps having a slope proportional to the first current; and
the control circuit is configured, at each second time period, to:
control a beginning of a first ramp at the beginning of the second time period,
compare the first ramp with a first threshold, and
terminate the second time period when the first ramp crosses the first threshold.

According to an embodiment:
the switched-mode power supply comprises a generator of second voltage ramps having a slope proportional to a constant current or proportional to Vsup-Vout; and
the control circuit is configured, at each first time period, to:
control a beginning of a second ramp at the beginning of the first time period,
compare the second ramp with a second threshold, and
terminate the first time period when the second ramp crosses the second threshold.

According to an embodiment:
the switched-mode power supply comprises a generator of first voltage ramps having a slope proportional to the first current; and
the control circuit is configured, at each second time period, to:
control a beginning of a first ramp at the beginning of the second time period,
compare the first ramp with a first threshold, and -
terminate the second time period when the first ramp crosses the first threshold;
the switched-mode power supply comprises a generator of second voltage ramps having a slope proportional to a fifth current proportional to Vsup-Vout;
the control circuit is configured, at each first time period, to:
control a beginning of a second ramp at the beginning of the first time period,
compare the second ramp with a second threshold, and
terminate the first time period when the second ramp crosses the second threshold; the switched-mode power supply comprises a fourth current source configured to supply the fifth current; and
the fourth current source comprises at least one current mirror with the first current source, the at least one current mirror being configured to supply the fifth current from the second current flowing through the first current source.

According to an embodiment, the switched-mode power supply is configured so that the second time period decreases when a difference Vsup-Vout decreases and the fourth current is not zero.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows an example of a switched-mode power supply;

FIG. 2 illustrates, with a timing diagram, the operation of the switched-mode power supply of FIG. 1;

FIG. 3 illustrates, with a timing diagram, a problematic phenomenon in the operation of the switched-mode power supply of FIG. 1;

FIG. 4 shows, in the form of blocks, an example of an embodiment of a circuit to solve the operating problem illustrated in FIG. 3;

FIG. 5 illustrates, in curves, the operation of the circuit of FIG. 4;

FIG. 6 illustrates, with a timing diagram, the operation of the switched-mode power supply of FIG. 1 comprising the circuit of FIG. 4;

FIG. 7 shows a more detailed example of implementation of the circuit of FIG. 4;

FIG. 8 shows a more detailed example of implementation of a current source of the circuit of FIGS. 4 and 7;

FIG. 9 shows a more detailed example of implementation of a circuit of the switched-mode power supply of FIG. 1 comprising the circuit of FIG. 4; and

FIG. 10 shows a more detailed example of implementation of a circuit of the switched-mode power supply of FIG. 1, comprising the circuit of FIG. 4.

### DETAILED DESCRIPTION OF ILLUSTRATIVE EMBODIMENTS

The same elements have been designated by the same The same elements have been designated by the same references in the various figures. In particular, structural and/or functional elements common to the different embodiments may have the same references and may have identical structural, dimensional and material properties.

For the sake of clarity, only those steps and elements that are useful for understanding the described embodiments have been shown and have been described in detail. In particular, the various known electronic systems and applications in which a switched-mode power supply can be used to supply a regulated voltage to a load to be powered have not been described, the described embodiments and variants being compatible with these known systems and applications.

Unless otherwise specified, when reference is made to two elements being connected to each other, this means directly connected without any intermediate elements other than conductors, and when reference is made to two elements being coupled to each other, this means that these two elements may be connected or may be connected via one or more other elements.

Unless otherwise specified, when it is indicated that a first quantity A is proportional to a second quantity B, this means that A is equal to D times B, with a constant multiplier coefficient.

In the following description, where reference is made to absolute position qualifiers, such as the terms "front", "back", "top", "bottom", "left", "right", etc., or relative position qualifiers, such as the terms "top", "bottom", "upper", "lower", etc., or orientation qualifiers, such as "horizontal", "vertical", etc., reference is made unless otherwise specified to the orientation of the drawings.

Unless specified otherwise, the expressions "about", "approximately", "substantially", and "in the order of" signify plus or minus 10% or 10°, preferably of plus or minus 5% or 5°.

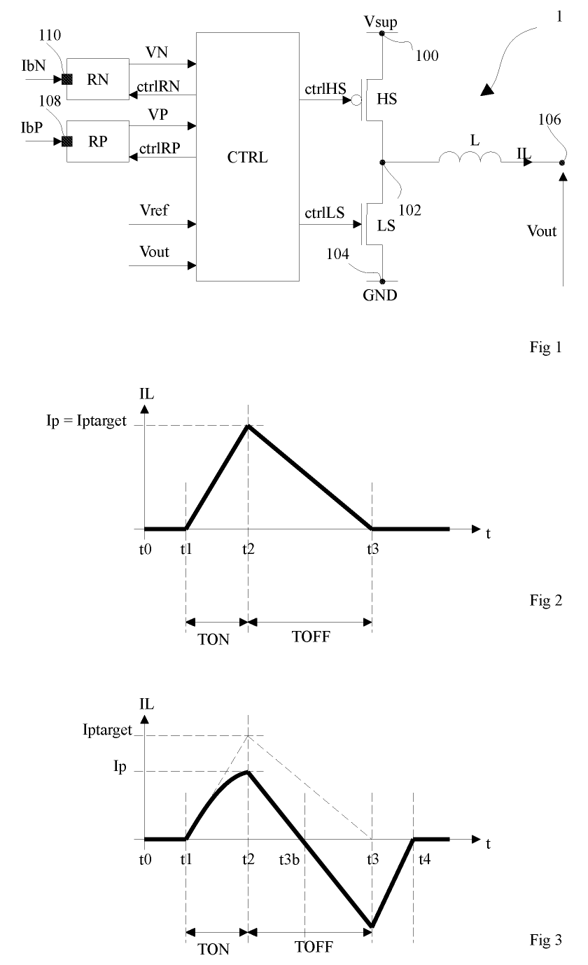

FIG. 1 shows an example of a switched-mode power supply 1.

Switched-mode power supply 1, also called DC-DC converter, is configured to supply, based on a power supply voltage Vsup, a voltage Vout regulated to a set point value Vtarget determined by a reference voltage Vref, voltages Vout and Vsup being DC voltages. In the example of FIG. 1, converter 1 is of buck type, that is, voltage Vout is regulated to a set point value Vtarget lower than the value of power supply voltage Vsup. For example, the set point value Vtarget of voltage Vout is the value of voltage Vref.

Converter 1 comprises a high-side switch HS connected between a node (or conductor rail) 100 configured to receive power supply potential Vsup, and a node 102. Switch HS is controlled by a control signal ctrlHS. For example, switch HS is implemented by one or more metal-oxide-semiconductor (MOS) transistors, for example by a P-channel MOS transistor (or PMOS) having its source coupled, for example connected, to node 100, its drain coupled, for example connected, to node 102, and its gate receiving signal ctrlHS.

Converter 1 comprises a low-side switch LS connected between node 102 and a node (or conductor rail) 104 configured to receive a reference potential GND, for example ground. Potential Vsup is referenced to potential GND and is, in the example of FIG. 1, positive. Switch LS is controlled by a control signal ctrlLS. For example, switch LS is implemented by one or more MOS transistors, for example by an N-channel MOS transistor (or NMOS) having its source coupled, for example connected, to node 104, its drain coupled, for example connected, to node 102, and its gate receiving signal ctrlLS.

Node 102 is coupled by an inductor L to a node 104 for supplying regulated voltage Vout. A load (not shown in FIG. 1) to be powered is connected between node 106 and node 104. A smoothing capacitor may be connected between node 106 and node 104, in parallel with the load. As an example, inductor L has a first terminal coupled, for example connected, to node 102, and a second terminal coupled, for example connected, to node 106.

Converter 1 comprises a control circuit CTRL configured to supply signals ctrlHS and ctrlLS to switches LS and HS. Circuit CTRL is configured to control switches LS and HS so that converter 1 operates in pulse-frequency modulation (PFM) and in discontinuous conduction mode (DCM).

Circuit CTRL is configured, at each operating cycle of the switched-mode power supply, to control a time period TON in the on state of high-side switch HS, switch LS then being controlled to the off state.

Time period TON is, for example, constant, and is, for example, configured so that the maximum value, or peak value, of a current IL flowing through inductor L is the same for each operating cycle.

As an alternative example, time period TON is proportional to 1/(Vsup-Vout) and is, for example, configured so that the maximum value, or peak value, of a current IL flowing through inductor L is the same at each operating cycle and is not modified when voltage Vsup varies, for example because voltage Vsup is supplied by a discharging battery. As an example, French patent FR1911933 B1, US patent US11750095 B2, and Chinese patent application CN112713773 A describe a converter in which time period TON is proportional to 1/(Vsup-Vout).

Circuit CTRL is configured, for each operating cycle of the switched-mode power supply, to control a time period TOFF of low-side switch LS, the time period TOFF of the operating cycle starting at the end of the time period TON of this operating cycle. During each time period TOFF, switch HS is controlled to the off state.

In the example of FIG. 1, assuming that voltage Vout is regulated to its constant set point value Vtarget, time period TOFF is constant and determined so that, at the end of the time period TOFF of each operating cycle, the current IL in the inductor is zero.

As an example, after each operating cycle, a new operating cycle, and thus the time period TON of the cycle, begin if the value of voltage Vout is smaller than its set point value Vtarget determined by voltage Vref, for example equal to the value of voltage Vref.

As an example, at each operating cycle, time period TON is proportional to the inverse of a current IbP, that is, proportional to 1/IbP, this current IbP being either constant when time period TON is constant, or proportional to Vsup-Vout when time period TON is proportional to 1/(Vsup-Vout).

For example, this current IbP determines the slope of the voltage ramps VP supplied by a ramp generator RP. For example, the slope of the ramps VP is proportional to IbP. At each operating cycle, the time period TON of the cycle is then determined, for example, by comparing a voltage ramp VP with a threshold voltage determined by the set point value Vtarget of voltage Vout, for example by comparing ramp VP with voltage Vref. For example, for each time period TON, a ramp VP begins with this time period TON, and time period TON ends when ramp VP crosses the threshold voltage.

As an example, at each operating cycle, time period TOFF is proportional to the inverse of a current IbN, which is either constant, or proportional to Vsup-Vout.

For example, this current IbN determines the slope of voltage ramps VN supplied by a ramp generator RN. For example, the slope of ramps VN is proportional to IbN. At each operating cycle, the time period TOFF of the cycle is then determined, for example, by comparing a voltage ramp VN with a threshold voltage determined by the set point value Vtarget of voltage Vout, for example by comparing voltage ramp VN with voltage Vref. For example, for each time period TOFF, a ramp VN begins with this time period TOFF, and time period TOFF ends when ramp VN crosses the threshold voltage.

As an example, circuit CTRL receives set point voltage Vref and voltage Vout, for example to determine when the value of voltage Vout becomes lower than its set point value Vtarget determined by voltage Vref, so as to control the beginning of a new operating cycle.

As an example, circuit CTRL receives voltages VP and VN to compare them with respective thresholds determined by the set point value Vtarget of voltage Vout, so as to determine the time periods TON and TOFF of each cycle, and to supply signals ctrlHS and ctrlLS accordingly.

As an example, the beginning of each ramp VP is controlled by a signal ctrlRP supplied by circuit CTRL to ramp generator RP.

As an example, the beginning of each ramp VN is controlled by a signal ctrlRN supplied by circuit CTRL to ramp generator RN.

As an example, generator RP receives current IpP on an input 108.

As an example, generator RN receives current IbN on an input 110.

FIG. 2 illustrates, in a timing diagram, the operation of the switched-mode power supply 1 of FIG. 1. More particularly, FIG. 2 shows the variation over time t of a current IL in the inductor L of converter 1 during an operating cycle.

At time t0, current IL is zero. Switches HS and LS are in the off state. Switched-mode power supply 1 is between two operating cycles.

At a time t1 subsequent to time t0, although this is not shown in FIG. 2, voltage Vout becomes smaller than its set point voltage Vtarget, and circuit CTRL controls the beginning of a time period TON.

During time period TON, the current IL in the inductor increases. In general, it is considered that current IL increases with a slope A1 proportional to Vsup-Vout. In other words, it is considered that current IL increases linearly in inductor L.

At a time t2 subsequent to time t1 and corresponding to the end of time period TON, current IL then reaches its maximum value, or peak value, Ip for this operating cycle. Value Ip is equal to A1.TON, taking the approximation that current IL increases linearly in inductor L. Converter 1 is sized so that value Ip is equal to a target value Itarget, that is, so that A1.TON = Itarget.

The time t2 of end of time period TON also corresponds, to within dead times enabling to avoid cross-conduction, to the beginning of the time period TOFF of the operating cycle. During time period TOFF, current IL decreases. In general, it is considered that current IL decreases with a constant slope A2. For example, slope A2 is proportional to Vout, and when voltage Vout is regulated to its set point value Vtarget, slope A2 is then constant, for example constant with respect to Vsup.

At a time t3 subsequent to time t2, time period TOFF ends. As previously indicated, time period TOFF is determined, at least partly, based on target peak value Itarget, so that current IL is zero at time t3 of end of time period TOFF.

The operation described hereabove in relation with FIG. 2 is that observed in practice only when the difference Vsup - Vout is sufficiently large, for example greater than a threshold Th. Indeed, when difference Vsup - Vout decreases and, for example, becomes smaller than threshold Th, then parasitic phenomena which have been neglected when considering that the current IL increases with a slope A1 during each time period TON, and decreases with a slope A2 during each time period TOFF, become more significant. As a result, the observed operation is no longer as expected as illustrated in FIG. 2, but instead is that illustrated in FIG. 3.

FIG. 3 illustrates, in a timing diagram, a problematic phenomenon in the operation of the switched-mode power supply 1 of FIG. 1. More particularly, FIG. 2 illustrates the variation over time t of a current IL in the inductor L of converter 1 during an operating cycle.

In this example, voltage difference Vsup - Vout is sufficiently low for the approximation of a linear increase in current IL during each time period TON no longer to be valid.

Indeed, in practice, control signals ctrlHS and ctrlLS have a high level corresponding to voltage Vsup and a low level corresponding to a zero voltage.

As a result, when difference Vsup - Vout decreases because voltage Vsup decreases, and switch HS is controlled to the on state by the low level of signal ctrlHS, the difference between the low level of signal ctrlHS and voltage Vsup is smaller than expected, and switch HS is more resistive than expected. This further results in that the potential difference across inductor L during each time period TON is lower than expected, and is, for example, lower than a value below which the inductive effect in inductor L decreases and the weight of this inductive effect decreases with respect to the weight of the resistive effect in the inductor.

As a further result, when difference Vsup - Vout decreases because voltage Vsup decreases, and switch LS is controlled to the on state by the high level of signal ctrlLS, the high level of signal ctrlLS is lower than expected and switch LS is more resistive than expected.

Thus, in FIG. 3, as compared with what has been described in FIG. 2, during the time period TON between times t1 and t2, current IL increases less rapidly than expected. As a result, at time t3, current IL reaches a peak value Ip lower than the value Itarget for which time period TON has been determined.

Further, in FIG. 3, as compared with what has been described in FIG. 2, during the time period TOFF between times t2and t3, current IL decreases not only from a value Ip lower than the expected value Itarget, but also faster than expected because switch LS is more resistive than expected. As a result, current IL reaches a zero value at a time t3b prior to the expected time t3, and keeps on decreasing until time t3.

After time t3, in the example of FIG. 3 where time period TOFF is followed by a phase during which both switches HS and LS are in the off state, current IL increases until it becomes zero again at a time t4 subsequent to time t3.

The fact for current IL to be negative between times t3b and t4 decreases the energy efficiency of converter 1.

It could be considered increasing time period TON when voltage difference Vsup - Vbat falls below threshold Th leading to the operation observed in FIG. 3, so that even in this case, current IL reaches a value Ip equal to Itarget.

However, this will increase the amplitude of the oscillations ("ripple") on the value of output voltage Vout.

Further, this also risks increasing the value of voltage Vout, which will result in a decrease in difference Vsup - Vout, and thus in an increase in unwanted parasitic phenomena leading to the operation described in relation with FIG. 3.

Rather than increasing time period TON when difference Vsup - Vout decreases and is below threshold Th, it is here provided to decrease time period TOFF with difference Vsup - Vout when this difference becomes lower than threshold Th.

For this purpose, it is provided, in a switched-mode power supply 1 where time period TOFF is proportional to the inverse of a constant current IbN or proportional to Vsup - Vout, to make time period TOFF inversely proportional to a current IbNcorr which is equal to current IbN plus a correction current Icorr, current Icorr being zero when a current Iprop proportional to Vsup - Vout is greater than a constant current Icst, and proportional to difference Icst - Iprop when current Iprop is lower than current Icst. A correction circuit, configured to supply current IbNcorr instead of current IbN, and to make time period TOFF proportional to the inverse of current IbNcorr rather than to the inverse of current IbN as described in relation with FIG. 1, is more particularly provided. The correction circuit is in particular configured to compare current Iprop with current Icst, so as to determine whether current Icorr is zero or proportional to difference Icst - Iprop.

According to an embodiment, when the correction circuit is implemented in a switched-mode power supply so that time period TOFF is proportional to the inverse of current IbNcorr, the switched-mode power supply is configured so that time period TOFF decreases when a difference Vsup-Vout decreases and current Icorr is non-zero.

According to an embodiment, the correction circuit is added to the switched-mode power supply 1 of FIG. 1, and the current IbN supplied to ramp generator RN is replaced by the current IbNcorr supplied by the current correction circuit.

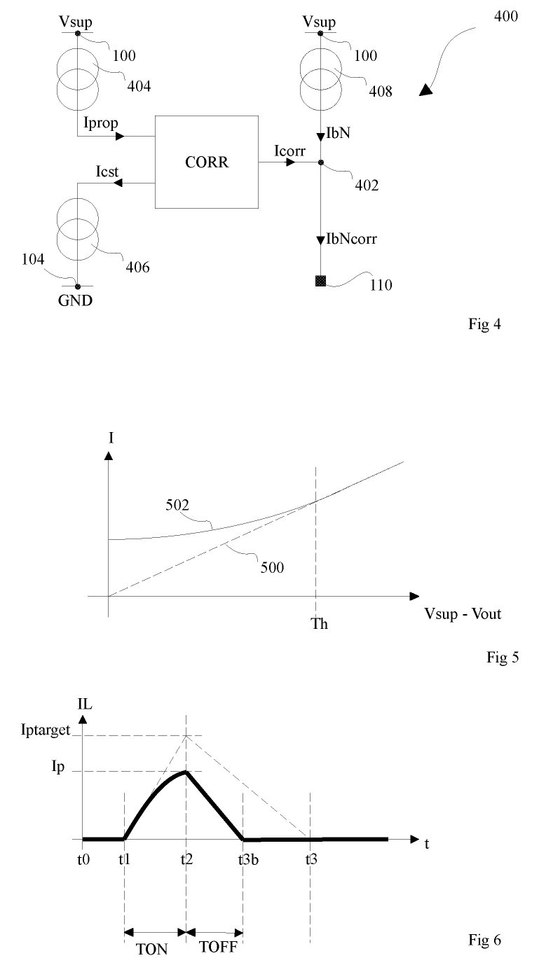

FIG. 4 shows, in the form of blocks, an example of an embodiment of such a correction circuit 400 configured to supply current IbNcorr and thus solve the operating problem illustrated in FIG. 3.

Circuit 400 comprises a circuit CORR for generating current Icorr. Circuit CORR is configured to supply current Icorr to a current summing node 402. For example, current Icorr is positive when it flows from circuit CORR to node 402.

Circuit 400 comprises a current source 404 configured to supply current Iprop to circuit CORR. For example, current Iprop is positive when it flows from current source 404 to circuit CORR. For example, current source 404 is connected between node 100 and circuit CORR.

Circuit 400 comprises a current source 406 configured to supply constant current Icst to circuit CORR. For example, current Icst is positive when it flows from circuit CORR to current source 406. For example, current source 406 is connected between node 104 and circuit CORR.

Circuit 400 comprises a current source 408 configured to supply current IbN to node 402. Thus, current IbNcorr is available at node 402, for example can be drawn from node 402, and is equal to IbN + Icorr. For example, current IbN is positive when it flows from current source 408 to node 402. For example, current source 408 is connected between node 100 and node 402. For example, node 402 is connected to the input 110 of the ramp generator RN of the power supply 1 of FIG. 1.

FIG. 5 illustrates, by means of curves, the operation of the circuit 400 of FIG. 4.

More particularly, FIG. 5 illustrates in a curve 500 the variation of current IbN with difference Vsup - Vout in an example where this current IbN is proportional to difference Vsup - Vout, and in a curve 500 the variation of the corresponding current IbNcorr supplied by circuit 400.

For values of voltage difference Vsup - Vout greater than threshold Th, that is, as long as current Iprop is greater than current Icst, current Icorr is zero and current IbNcorr (curve 502) is equal to current IbN (curve 500). As a result, duration TOFF is determined as described in relation to FIG. 1.

On the other hand, for values of voltage difference Vsup - Vout smaller than threshold Th, that is, as long as current Iprop is lower than current Icst, current IbNcorr increases when difference Vsup - Vout decreases, to become substantially constant and equal to a value IbNcst determined by current Icst. Indeed, when difference Vsup - Vout decreases, current Iprop decreases, whereby current Icorr equal to Icst - Iprop increases from a zero value when current Iprop is equal to current Icst, that is, when difference Vsup - Vout is equal to threshold Th.

Since time period TOFF is proportional to the inverse of current IbNcorr, it follows that, for values Vsup - Vout smaller than threshold Th, when value Vsup - Vout decreases and current IbNcorr increases, time period TOFF decreases as compared with a case where time period TOFF would have been proportional to the inverse of current IbN.

FIG. 6 illustrates, in a timing diagram, the operation of the switched-mode power supply of FIG. 1 comprising the circuit of FIG. 4, when time period TOFF is proportional to the inverse of current IbNcorr rather than to the inverse of current IbN. More particularly, FIG. 6 illustrates the variation as a function of time t of a current IL in the inductor L of converter 1 during an operating cycle, while the voltage difference Vsup - Vout is smaller than threshold Th.

The variation of current IL between times t0 and t3b is the same as that described in relation with FIG. 3.

However, in the example of FIG. 6, since voltage Vsup - Vout is lower than threshold Th, current IbNcorr is greater than current IbN, whereby the time period TOFF in FIG. 6 is shorter than that in FIG. 3. In particular, as shown in FIG. 6, by appropriately selecting the value of current Icst and the proportionality factor between current Iprop and difference Vsup - Vout, time period TOFF ends at time t3b.

Thus, when current IL becomes zero, time period TOFF ends and current IL then remains zero.

As a result, the energy efficiency of the switched-mode power supply 1 comprising circuit 400 is improved with respect to the case shown in FIG. 1, where the switched-mode power supply does not comprise circuit 400.

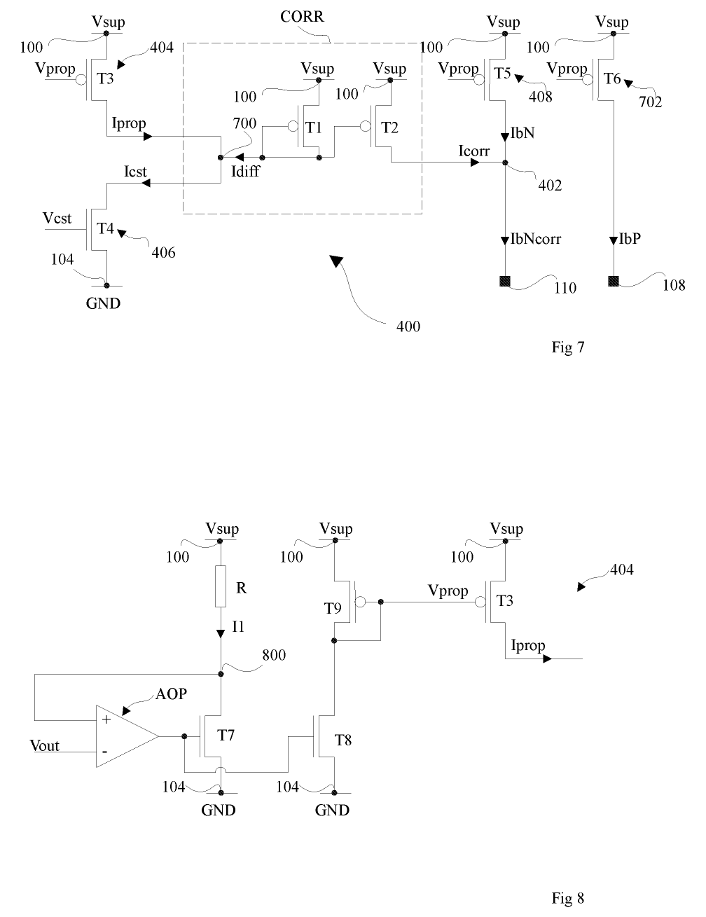

FIG. 7 shows a more detailed example of implementation of the circuit 400 of FIG. 4. More particularly, FIG. 7 shows a more detailed example of implementation of circuit CORR.

In the example of embodiment of FIG. 7, circuit CORR comprises a MOS transistor T1. Transistor T1 has its gate and drain connected to a node 700. Node 700 is a comparison node enabling to compare current Iprop and current Icst, that is, difference Vsup - Vout with threshold Vth. Node 700 is more particularly configured to receive current Iprop and constant current Icst, so that transistor T1 is off when current Iprop is greater than constant current Icst, and is on when current Iprop is smaller than constant current Icst. Further, when transistor T1 is on, a current Idiff equal to Icst - Iprop flows through transistor T1.

As an example, transistor T1 has a P channel and has its source coupled, preferably connected, to the node 100 receiving potential Vsup.

The circuit 700 of the example of FIG. 7 further comprises a MOS transistor T2 assembled as a mirror with transistor T1, and configured to supply current Icorr to node 402. Due to the fact that transistors T1 and T2 are assembled as a current mirror, current Icorr flowing through transistor T2 is proportional, for example equal, to the current Idiff flowing through transistor T1.

Since current Idiff is zero when current Iprop is greater than current Icst, and is equal to Icst - Iprop when current Iprop is smaller than current Icst, current Icorr is thus zero when current Iprop is greater than current Icst (Vsup - Vout greater than Th, and is proportional to Icst - Iprop when current Iprop is smaller than current Icst (Vsup - Vout smaller than Th).

As an example, transistor T2 has a P channel and has its gate coupled, preferably connected, to the gate of transistor T1, its source coupled, preferably connected, to node 100, and its drain coupled, preferably connected, to node 402.

As an example, as shown in FIG. 7, current source 404 comprises a MOS transistor T3, for example with a P channel. For example, transistor T3 has its source coupled, preferably connected, to node 100, and its drain coupled, preferably connected, to node 700. The gate of transistor T3 receives a potential Vprop configured so that the current Iprop flowing through transistor T3 is proportional to the difference Vsup - Vout.

As an example, as shown in FIG. 7, current source 406 comprises a MOS transistor T4, for example with an N channel. For example, transistor T4 has its source coupled, preferably connected, to node 100, and its drain coupled, preferably connected, to node 700. The gate of transistor T4 receives a constant potential Vcst determining the value of the constant current Icst flowing through transistor T4.

As an example, as shown in FIG. 7, current source 408 comprises a MOS transistor T5, for example with a P channel. For example, transistor T5 has its source coupled, preferably connected, to node 100, and its drain coupled, preferably connected, to node 402. The gate of transistor T5 receives a potential configured so that the current Iprop flowing through transistor T3 is proportional to current IbN.

For example, the potential applied to the gate of transistor T5 is configured so that current IbN is proportional to difference Vsup - Vout. According to an embodiment, current source 408 then comprises a current mirror with current source 404 so that current IbN is proportional or equal to current Iprop. For example, the potential applied to the gate of transistor T5 is potential Vprop, and transistor T5 is mirror-assembled with transistor T3.

As another example, the potential applied to the gate of transistor T5 is configured so that current IbN is constant.

According to an embodiment, circuit 400 is further configured to supply the current IpP determining the value of time period TON. In this case, circuit 400 comprises a current source 702 configured to supply current IbP, for example to the input 108 of the ramp generator VP of the switched-mode power supply 1 of FIG. 1. For example, current source 702 is connected between node 100 and input 108. For example, current source 702 comprises a MOS transistor T6 configured to supply current IbP. For example, MOS transistor T6 has a P channel and has its source coupled, preferably connected, to node 100, and its gate receiving a potential determining the value of the current IbP flowing through transistor T6.

In particular, in the case where current IbP is proportional to difference Vsup - Vout, current source 702 may comprise a current mirror with current source 404 so that current IbP is equal or proportional to current Iprop. For example, transistor T6 is mirror-assembled with transistor T3 and receives potential Vprop on its gate.

FIG. 8 shows a more detailed example of implementation of the current source 402 of the circuit 400 of FIGS. 4 and 7.

Current source 404 comprises a MOS transistor T7 and a resistor R series-connected between nodes 100 and 104. Current source 404 further comprises an operational amplifier AOP. Amplifier AOP is configured to control transistor T7 so that the voltage across resistor R is equal to Vsup - Vout, and a current I1 flowing through resistor R is then equal to (Vsup - Vout)/R, and is thus proportional to Vsup - Vout.

For example, a first input of amplifier AOP, for example the non-inverting (+) input, is coupled, preferably connected, to a node 800 connecting transistor T7 to resistor R, a second input of amplifier AOP, for example the inverting input (-), is configured to receive the regulated voltage Vout, and an output of the amplifier is connected to the gate of transistor T7.

Current source 404 further comprises at least one current mirror configured to supply current Iprop from the current I1 flowing through transistor T7.

For example, transistor T7 has an N channel and its source coupled, preferably connected, to node 104, its drain coupled, preferably connected, to node 800.

For example, current source 404 comprises two current mirrors to supply current Iprop from current I1. For example, a first current mirror comprises a MOS transistor T8 mirror-assembled with transistor T7. For example, transistor T8 has a P channel and has its source coupled, preferably connected, to node 104, and its gate coupled, preferably connected, to the gate of transistor T7. For example, a second current mirror comprises transistor T9 series-connected with transistor T8, and transistor T3 mirror-assembled with transistor T9. For example, transistor T9 has an N channel, and has its source coupled, preferably connected, to node 100, its drain connected to the gate of transistor T9 and the drain of transistor T8, and its gate connected to the gate of transistor T3. Potential Vprop is then available on the gate of transistor T9.

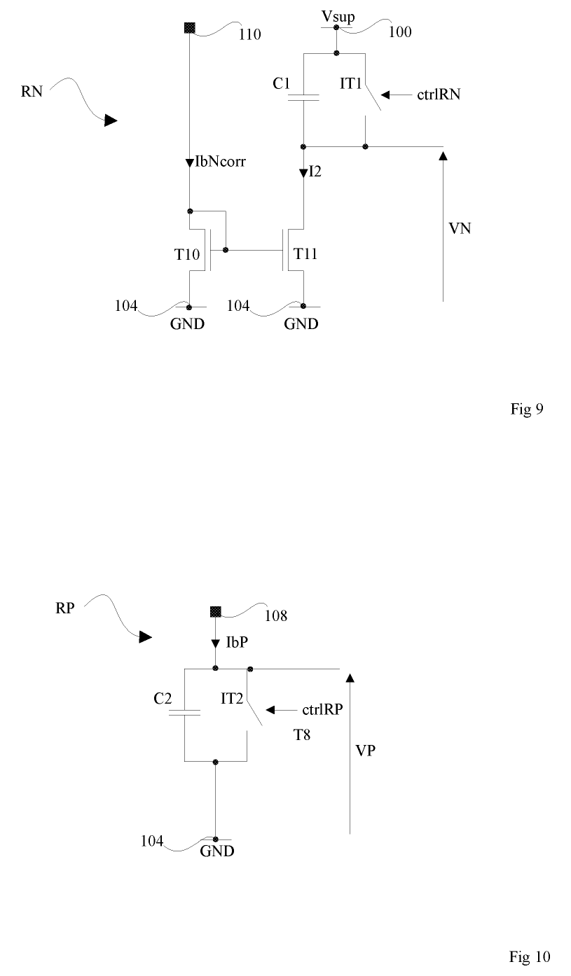

FIG. 9 shows a more detailed example of implementation of the ramp generator RN of the switched-mode power supply 1 of FIG. 1, in the case where the input 110 of generator RN receives current IbNcorr. In this example, ramps VN are ramps decreasing from potential Vsup.

Ramp generator RN comprises a capacitor C1 and a switch IT1 connected in parallel. The parallel association of the capacitor and of the switch is configured to receive a charge (increasing VN ramp) or discharge (decreasing VN ramp) current from capacitor C1, this charge or discharge current being proportional to current IbNcorr.

In this example, generator RN comprises a current mirror comprising an N-channel MOS transistor T10 connected between input 110 and node 104, and an N-channel MOS transistor T11 mirror-assembled with transistor T10.

For example, transistor T10 has its source coupled, preferably connected, to node 104, its drain coupled, preferably connected, to input 110 and to the gate of transistor T10, and its gate connected to the gate of transistor T11, the source of transistor T11 being coupled, preferably connected, to node 104. Thus, the current I2 in transistor T11 is proportional to current IbNcorr, for example equal to current IbNcorr.

In the example of FIG. 9, the parallel association of capacitor C1 and of switch IT1 receives current I2. For example, the parallel association of capacitor C1 and of switch IT1 is connected between transistor T11, for example the drain of transistor T11, and node 100. Voltage ramps VN are available on the terminal of the parallel association of capacitor C1 and of switch IT1, which is connected to transistor T11. Switch IT1 is controlled by signal crtlRN so that, in the example shown in FIG. 9, switch IT1 is switched from the on state to the off state at the beginning of a ramp VN, and is switched from the off state to the on state at the end of each ramp VN, for example as a response to the detection that ramp VN has crossed the threshold voltage determined by voltage Vref.

FIG. 10 shows a more detailed example of implementation of the ramp generator RP of the switched-mode power supply 1 of FIG. 1, the input 108 of generator RP receiving current IbP. In this example, ramps VP are ramps increasing from a zero value.

Ramp generator RN comprises a capacitor C2 and a switch IT2 connected in parallel. The parallel association of capacitor C2 and of switch IT2 is configured to receive a charge (increasing VP ramp) or discharge (decreasing VP ramp) current from capacitor C2, this charge or discharge current being proportional to current IbP.

In this example, generator RP does not comprise a current mirror configured to supply the charge or discharge current to capacitor C2 from current IbP, although this may be the case in other examples.

In the example of FIG. 10, the parallel association of capacitor C2 and of switch IT2 receives charge current IbP directly from capacitor C2. For example, the parallel association of capacitor C2 and of switch IT2 is connected between input 108 and node 104. Switch IT2 is controlled by signal crtlRP so that, in the example of FIG. 10, switch IT2 is switched from the on state to the off state at the beginning of a ramp VP, and is switched from the off state to the on state at the end of each ramp VP, for example as a response to the detection that ramp VP has crossed the threshold voltage determined by voltage Vref.

Various embodiments and variants have been described. Those skilled in the art will understand that certain features of these various embodiments and variants may be combined, and other variants will occur to those skilled in the art. In particular, the implementations of circuit CORR, of current source 404, of the other current sources, and of ramp generators RP and RN are not limited to the examples described hereabove. For example, it is possible to invert, in the circuit 400 of FIG. 7, the potentials Vsup and GND received by the respective nodes 100 and 104 of this circuit by replacing each N-channel transistor with a P-channel transistor and vice versa. A similar modification can be made in the circuit of FIG. 8, in the circuit of FIG. 9, and/or in the circuit of FIG. 10.

Finally, the practical implementation of the described embodiments and variants is within the abilities of those skilled in the art based on the functional indications given hereabove. In particular, those skilled in the art are capable of determining the value of threshold Th, for example from computer-assisted simulations, to determine the value of the difference Vsup - Vout below which, without circuit 400, the operation described in relation with FIG. 3 occurs, that is, the value of the difference Vsup - Vout from which lower values of this difference Vsup - Vout result in a negative current IL at the end of time period TOFF if circuit 400 is not used. Further, those skilled in the art are also capable of determining the value of current Icst and the proportionality coefficients between current Iprop and the difference Vsup - Vout, between current Idiff and current Icorr, and between current IbN and difference Vsup - Vout so that, at the end of each time period TOFF, current IL is zero.

What is claimed is:

1. A switched-mode power supply comprising:
a high-side switch connected between a first node configured to receive a power supply potential (Vsup) and a second node configured to be coupled by an inductor to a supply node configured to supply a regulated voltage (Vout);
a low-side switch connected between the second node and a third node configured to receive a reference potential;
a control circuit for controlling the high-side and low-side switches and configured to, at each operating cycle:
control a first time period in an on state of the high-side switch, the first time period being constant or proportional to 1/(Vsup-Vout); and
control, at an end of the first time period, a second time period in an on state of the low-side switch, the second time period being proportional to an inverse of a first current; and
a correction circuit configured to:
compare a second current proportional to Vsup-Vout with a constant current; and
supply the first current equal to a third current plus a fourth current, the fourth current being zero when the second current is greater than the constant current, and proportional to a subtraction of the second current from the constant current when the second current is smaller than the constant current.

2. The switched-mode power supply according to claim 1, wherein the control circuit is configured to control the high-side and low-side switches in pulse-frequency modulation and in discontinuous conduction mode.

3. The switched-mode power supply according to claim 1, wherein the correction circuit comprises:
a first circuit for generating the fourth current and configured to supply the fourth current to a current summing node;
a first current source configured to supply the second current to the first circuit for generating the fourth current;
a second current source configured to supply the constant current to the first circuit for generating the fourth current; and
a third current source configured to supply the third current to the current summing node, the first current being available on the current summing node.

4. The switched-mode power supply according to claim 3, wherein the first circuit for generating the fourth current comprises:
a first metal-oxide-semiconductor (MOS) transistor having its gate and its drain connected to a current comparison node configured to receive the second current and the constant current so that:
the first MOS transistor is turned off when the second current is greater than the constant current; and
the first MOS transistor is on when the second current is smaller than the constant current, and a current equal to the subtraction of the second current from the constant current flows through the first MOS transistor; and
a second MOS transistor assembled as a current mirror with the first MOS transistor, and configured to supply the fourth current.

5. The switched-mode power supply according to claim 3, wherein the first current source comprises:
a MOS transistor and a resistor in series between the first and third nodes;
an operational amplifier having a first input connected to a fourth node connecting the MOS transistor to the resistor, a second input configured to receive the regulated voltage, and an output connected to a gate of the MOS transistor; and
at least one current mirror configured to supply the second current from a current flowing through the MOS transistor.

6. The switched-mode power supply according to claim 5, wherein the third current source comprises at least one second current mirror configured to supply the third current from the current flowing through the MOS transistor of the first current source.

7. The switched-mode power supply according to claim 3, wherein the third current source comprises at least one current mirror with the first current source, the current mirror being configured to supply the third current from the second current flowing through the first current source.

8. The switched-mode power supply according to claim 1, wherein the third current is constant or proportional to 1/(Vsup - Vout).

9. The switched-mode power supply according to claim 1, wherein:
the switched-mode power supply comprises a generator of first voltage ramps having a first slope proportional to the first current; and
the control circuit is configured, at each second time period, to:
control a beginning of a first ramp at a beginning of the second time period;
compare the first ramp with a first threshold; and
terminate the second time period when the first ramp crosses the first threshold.

10. The switched-mode power supply according to claim 9, wherein:
the switched-mode power supply comprises a generator of second voltage ramps having a second slope proportional to a current constant or proportional to Vsup - Vout; and
the control circuit is configured, at each first time period, to:
control a beginning of a second ramp at a beginning of the first time period;
compare the second ramp with a second threshold; and
terminate the first time period when the second ramp crosses the second threshold.

11. The switched-mode power supply according to claim 3, wherein:
the switched-mode power supply comprises a generator of first voltage ramps having a first slope proportional to the first current; and
the control circuit is configured, at each second time period, to:
control a beginning of a first ramp at a beginning of the second time period;
compare the first ramp with a first threshold; and
terminate the second time period when the first ramp crosses the first threshold;
the switched-mode power supply comprises a generator of second voltage ramps having a second slope proportional to a fifth current proportional to Vsup-Vout;
the control circuit is configured, at each first time period, to:
control a beginning of a second ramp at a beginning of the first time period;
compare the second ramp with a second threshold; and
terminate the first time period when the second ramp crosses the second threshold;
the switched-mode power supply comprises a fourth current source configured to supply the fifth current; and
the fourth current source comprises at least one current mirror with the first current source, the at least one current mirror being configured to supply the fifth current from the second current flowing through the first current source.

12. The switched-mode power supply according to claim 1, wherein the switched-mode power supply is configured so that the second time period decreases when a difference Vsup - Vout decreases and the fourth current is not zero.

13. A method of controlling a switched-mode power supply comprising a high-side switch connected between a first node and a second node, and a low-side switch connected between the second node and a third node, the method comprising:
receiving, by the first node, a power supply potential (Vsup);
supplying, by a supply node coupled via an inductor to the second node, a regulated voltage (Vout);
receiving, by the third node, a reference potential; and
at each operating cycle, controlling, by a control circuit:
a first time period in an on state of the high-side switch, the first time period being constant or proportional to 1/(Vsup - Vout); and
at an end of the first time period, a second time period in an on state of the low-side switch, the second time period being proportional to an inverse of a first current;
comparing, by a correction circuit, a second current proportional to Vsup-Vout with a constant current; and
supplying, by the correction circuit, the first current equal to a third current plus a fourth current, the fourth current being zero in response to the second current being greater than the constant current, and proportional to a subtraction of the second current from the constant current in response to the second current being smaller than the constant current.

14. The method according to claim 13, further comprising controlling, by the control circuit, the high-side and low-side switches in pulse-frequency modulation and in discontinuous conduction mode.

15. The method according to claim 13, further comprising:
generating, by a first circuit of the correction circuit, the fourth current and supplying the fourth current to a current summing node;
supplying, by a first current source of the correction circuit, the second current to the first circuit for generating the fourth current;
supplying, by a second current source of the correction circuit, the constant current to the first circuit for generating the fourth current; and
supplying, by a third current source of the correction circuit, the third current to the current summing node, the first current being available on the current summing node.

16. The method according to claim 15, wherein the first circuit comprises a first metal-oxide-semiconductor (MOS) transistor having its gate and its drain connected to a current comparison node, and the method comprises:
receiving, by the current comparison node, the second current and the constant current;
turning off the first MOS transistor in response to the second current being greater than the constant current;
turning on the first MOS transistor in response to the second current being smaller than the constant current, and a fifth current equal to the subtraction of the second current from the constant current flowing through the first MOS transistor; and
supplying, by a second MOS transistor of the first circuit forming a current mirror with the first MOS transistor, the fourth current.

17. The method according to claim 13, wherein the third current is constant or proportional to 1/(Vsup-Vout).

18. The method according to claim 13, further comprising:
generating, by a first generator, first voltage ramps having a first slope proportional to the first current; and
at each second time period:
controlling, by the control circuit, a beginning of a first ramp at a beginning of the second time period;
comparing, by the control circuit, the first ramp with a first threshold; and
terminating, by the control circuit, the second time period when the first ramp crosses the first threshold.

19. The method according to claim 18, further comprising:
generating, by a second generator, second voltage ramps having a second slope proportional to a current constant or proportional to Vsup-Vout;
at each first time period:
controlling, by the control circuit, a beginning of a second ramp at a beginning of the first time period;
comparing, by the control circuit, the second ramp with a second threshold; and
terminating, by the control circuit, the first time period when the second ramp crosses the second threshold.

20. The method according to claim 13, further comprising decreasing the second time period in response to a difference Vsup - Vout decreasing and the fourth current not being zero.
